(19) United States
(12) Patent Application Publication
(10) Pub. No.: US 2005/0149799 A1
(43) Pub. Date: Jul. 7, 2005

(54) Integrated circuit with leakage control and method for leakage control

(75) Inventors: Teppo Hemia, Tampere (FI); Petri Vaisanen, Tampere (FI); Pasi Kolinummi, Kangasala (FI)

Correspondence Address: WARE FRESSOLA VAN DER SLUYS &;ADOLPHSON, LLP, BRADFORD GREEN BUILDING 5, 755 MAIN STREET, P O BOX 224, MONROE, CT, 06468, US

(73) Assignee: Nokia Corporation

(21) Appl. No.: 11/001,810

(22) Filed: Dec. 1, 2004

(30) Foreign Application Priority Data
Dec. 1, 2003 (WO) PCT/IB03/05544

(51) Int. Cl. H03L 7/00; G01R 31/28

(52) U.S. Cl. 714/726

(57) ABSTRACT

The present invention relates to integrated circuit with reduced leakage power and in particular to a methodology for retaining an operational state of at least a part of the integrated circuit while the part is in standby/low power mode. In detail, the inventive methodology is based on the use of scan chains being implemented in the integrated circuit for production testing purposes. Via the scan chains circuit-internal state-variable memory element content is read out and/or written in such that the operational state of for instance a specific part (power domain) of the integrated circuit may be captured on the basis of the circuit internal contents, retained in an adequately provided data storage and afterwards scanned into the specific part of the integrated circuit to restore the operational state thereof.

### CROSS-REFERENCE TO RELATED APPLICATION

This application claims priority from International Application Number PCT/IB2003/005544 filed Dec. 1, 2003.

### BACKGROUND OF THE INVENTION

1. Technical Field

The present invention relates to an integrated circuit with reduced leakage power and in particular to a method for retaining an operational state of at least a part of the integrated circuit while said part is in standby/low power mode.

2. Discussion of Related Art

Today's integrated circuits are based on CMOS technology which scales continuously to deep-sub-micron dimensions and allows the realization of highly integrated circuits in the form of system-on-a-chip (SoC) circuits, wherein such an advance in computation performance levels have been previously seen only on desktop computers. The implementation of such highly integrated circuits provides the capability of high-speed, low-power computation for portable devices thereby opening up new possibilities and applications. Cellular phones with video streaming capability connected to a steaming server represent only one example of numerous consumer electronics taking advantage of the increasing computation performance that can be realized with up-to-date highly integrated circuits. A simple continuous downscaling of structures in the integrated circuits manufactured on the basis of current available technologies, however, does not meet all requirements and poses additional problems. The power consumption design of today's highly integrated circuits becomes one main focus, which relates in particular to battery/accumulator-operated portable devices. New circuit techniques and design methodologies are necessary to maximize the use of deep-sub-micron technology while maintaining an acceptable power consumption level.

The power dissipation and thus the power consumption of a typical integrated circuit consists of several main components comprising dynamic switching power, short-circuit power, static power and leakage power. Whereas the first two power dissipation components result from actively switching states of the circuits, the last two components are always present and do not depend on the state changes of the circuits. Particularly for portable devices with a high ratio of standby to active operation, the static power and leakage power may be the dominant factors in determining overall battery/accumulator life. Nevertheless, with downscaling of the deep-sub-micron processes the portion of static leakage power becomes also remarkable even in the active mode of integrated circuit operation.

In detail, the present invention will relate to leakage power and especially to leakage power of integrated circuits in non-active mode conventionally designated as so-called standby, low power, or sleep modes.

There are several techniques discussed and available to overcome the above described power consumption problem, but all of them have inherent disadvantages and specific restrictions which will prevent them from use in a unified way for a whole complex system on a chip. A selection of possible techniques will be mentioned below to recite typically inherent disadvantages and specific restrictions.

For instance a software-based save and restore mechanism can be employed. A software component saves circuit context into an on-chip memory that can be placed in retention afterwards or the software component saves the circuit context into an external memory. This mechanism is highly flexible, does not require any changes in the circuit design and allows a powering down of the most part of the circuit resulting in an efficient leakage reduction. Unfortunately, the software implementation is very complex, the transition time is high and the states of internal state machines cannot be saved and restored. Moreover, the read and write accesses to an external memory consume power.

Alternatively, the operation voltage of the circuits may be reduced. A significant reduction factor in leakage power can be obtained by scaling down the operation voltage. Whereas such a technique has a slight impact on the cost, the transition time is significantly increased. Moreover, external cap energy is wasted and the operation voltage reduction is only efficient on medium leakage processes and especially not efficient enough on high leakage processes. The power control logic has to be adapted to support the operation voltage reduction requiring cost-intensive and time-intensive re-design.

A further alternative is given by the use of retention flip-flops having built-in low leakage retention cells. Such retention flip-flops allow for hardware-based save and restore of the state of integrated circuits (including internal state machines) on transition with full retention being transparent to software. Advantageously, retention flip-flops are applicable in high frequency domain switching, have a negligible impact on the performance of the integrated circuit, into which retention flip-flops are implemented, and allow for efficiently reducing leakage power due to the fact that the most part of the circuit is enabled for powering down. A first major disadvantage is posed by the dimensions of retention flip-flops, which require a significantly larger implementation area causing a significant increase of the total die size, which is of course cost-intensive. A second major disadvantage of such retention flip-flops is their impact on the front end RTL (register transfer level) design at module level which may require a complete re-design. The transition time of retention flip-flops is disadvantageous.

In summary, the implementation of retention techniques and requirements must be based on a careful analysis per each power domain of integrated circuits to select one or more appropriate techniques. Each retention technique has an associated break even time, which needs to be assessed to meet the economic requirements, which are mainly determined by trade-offs between transition latency, cost and software and hardware implementation complexity, respectively. Some power domains may require retention flips-flops or may be kept active at low voltage while other power domains could be handled with a mix of save/restore, memory retention or partial retention techniques. Especially, integrated circuits in high leakage processes may be implemented on the basis of retention flip-flops, memory retention and save/restore technique.

It shall be additionally noted that although the power consumption problem has been posed in conjunction with portable devices having high computation performance, the power consumption effects likewise also affect non-portable devices such as desktop devices. Due to the fact that high power consumption results in parallel high power dissipation, heating up of such devices is caused thereby, which for instance requires therefore among others cost-intensive cooling mechanisms of complex design.

### DISCLOSURE OF INVENTION

The object of the invention is to provide improved leakage power control in integrated circuits and in particular reduced leakage power in integrated circuits with low power mode, which is associated with loss of contents of memory elements within the integrated circuit.

The object of the present invention is solved by employing scan design for testability (DFT) precautions, namely scan chains, for observing and/updating circuit-internal state-variable memory elements. The ability to observe circuit-internal memory elements enables to capture an operational mode of at least a partition within the integrated circuit to be retained. The ability to update circuit-internal memory elements enables restoration of an operational mode of at least a partition within the integrated circuit on the basis of stored memory element data.

The inventive concept can be applied onto any integrated circuit designs being structured in accordance with scan design for testability requirements without requiring complex, difficult or cost- and time-intensive modifications thereof. Scan chains themselves are provided and exist conventionally in today's integrated circuit design to enable production testing. The modification on the integrated circuit design in accordance with the inventive concept mainly relates to internal scan inputs and outputs which have to be coupled suitably with a storage component. The front end design with the exception of the implemented routing from the scan chains to the specific storage component is maintained unmodified. Due to the fact that the inventive concept is based on scan chains in accordance with scan design for testability a granularity of the inventive concept corresponds to the granularity of the scan chain implementation, which means that a selection of the scan chains and all scan chains are applied therefor, respectively. The leakage power can be reduced significantly during an integrated circuit in question is in low power mode, which may correspond to sleep mode, a power down mode, a mode with reduced power supply and the like, since powering up into power mode of the integrated circuit in question need not maintain any contents of memory elements therein.

According to a first aspect of the present invention, a method for controlling leakage power in an integrated circuit is provided. The integrated circuit implements several scan chains allowing for updating internal state-variable memory elements with test patterns for production testing purposes. Further, the integrated circuit is operable with at least a power mode and a low power mode. The power mode corresponds to an active mode; i.e. the integrated circuit operates in the active mode in accordance with its designated purpose. The low power mode corresponds to a non-active mode in which power consumption is reduced; i.e. the low power mode may correspond to a mode with reduced power supply of the integrated circuit, a power-down mode within which the integrated circuit is powered down and the like. An operational state of at least one partition of the integrated circuit, which is operated with the low power mode, is restored by retrieving data from a data storage and scanning the retrieved data in the integrated circuit. The scanning in is performed by using at least a part of the scan chains that may be associated with the partition to update at least a part of internal state-variable memory elements of the partition with the retrieved data.

According to an embodiment of the invention, the at least one partition is switched to operate in power mode and the at least one partition in question is operated in scan mode to enable the scanning in.

According to another embodiment of the invention, retrieved data corresponds to default data. The default data allow restoring the partition of the integrated circuit to operate in a default operational state.

According to yet another embodiment of the invention, the scan chains additionally allow for observing the internal state-variable memory elements. The operational state of the partition of the integrated circuit, which is operated with power mode, is saved by capturing data on the basis of an observation, i.e. by observing at least a part of the internal state-variable memory elements via at least a part of the scan chains which are associated with the partition. The captured data is finally stored in the data storage. Additionally, the captured data allows for restoring afterwards the operational state of the at least one partition of the integrated circuit, which is active during observation.

According to a further embodiment of the invention, the at least one partition is operated in scan mode to enable observation and the at least one partition is switched into low power mode after successful observation.

According to an embodiment of the invention, the integrated circuit may be partitioned into one or more power domains each comprising at least a part of the integrated circuit and each being operable with at least the power mode and the low power mode. The scan chains are associated with said at least one power domain such that each power domain is updateable and observable.

According to an embodiment of the invention, the low power mode causes loss of contents of the internal state-variable memory elements such that restoring of an operational mode is required when re-powering the power domain of the partition to ensure proper operation of the integrated circuit.

According to another embodiment of the invention, the operational steps are carried out by a scan control function. The scan control function may be hardware-implemented or may be at lest partly software-implemented.

According to a second aspect of the present invention, an integrated circuit enabled with leakage power control is provided. The integrated circuit implements several scan chains allowing for updating internal state-variable memory elements and is additionally operable with at least one power mode and a low power mode. The scan chains are operable for restoring an operational state of the at least one partition; i.e. the at least a part of the scan chains of the at least one partition are employed to update at least a part of the internal state-variable memory elements with data that is retrieved from a data storage.

According to an embodiment of the invention, one or more inputs of the scan chains are coupled via a data path to the storage component.

According to another embodiment of the invention, the data corresponds to default data in order to restore the partition of the integrated circuit into a default operational state.

According to yet another embodiment of the invention, the several scan chains allow for observing the internal state-variable memory elements. The scan chains are operable for saving an operational state of the at least one partition. That means that at least a part of the scan chains of the at least one partition are employed to observe at least a part of the internal state-variable memory elements to capture data therefrom. The captured data is stored in the data storage.

Additionally, the captured data allows for restoring afterwards the operational state of the partition of the integrated circuit.

According to a further embodiment of the invention, one or more outputs of the scan chains are coupled via a data path to the storage component.

According to an embodiment of the invention, the integrated circuit comprises a scan control function enabling the updating and/or enabling the saving.

According to another embodiment of the invention, the scan chains are carried out in accordance with scan design for testability of the integrated circuit to allow for production testing.

According to a third aspect of the present invention, a system including one or more integrated circuits and a data storage is provided. The integrated circuits are enabled with leakage power control. The integrated circuits implement several scan chains allowing for updating internal state-variable memory elements and are additionally operable with at least one power mode and a low power mode. The scan chains are operable for restoring an operational state of the at least one partition of one of the integrated circuits; i.e. the at least a part of the scan chains of the at least one partition are employed to update at least a part of the internal state-variable memory elements with data that is retrieved from the data storage.

According to an embodiment of the invention, one or more inputs of the scan chains are coupled via a data path to the storage component.

According to another embodiment of the invention, the data corresponds to default data in order to restore the at least one partition of one of the integrated circuits into a default operational state.

According to yet another embodiment of the invention, the several scan chains allow for observing the internal state-variable memory elements. The scan chains are operable for saving an operational state of the at least one partition of one of the integrated circuits. That means that at least a part of the scan chains of the at least one partition are employed to observe at least a part of the internal state-variable memory elements to capture data therefrom. The captured data is stored in the data storage. Additionally, the captured data allows for restoring afterwards the operational state of the at least one partition of one of the integrated circuits.

According to a further embodiment of the invention, one or more outputs of the scan chains are coupled via a data path to the storage component.

According to an embodiment of the invention, the system comprises a scan control function enabling the updating and/or enabling the saving.

### BRIEF DESCRIPTION OF THE DRAWINGS

The accompanying drawings are included to provide a further understanding of the invention and are incorporated in and constitute a part of this specification. The drawings illustrate embodiments of the present invention and together with the description serve to explain the principles of the invention. In the drawings,

FIG. 1 illustrates schematically a scan chain within an example circuit under test;

FIG. 2 illustrates schematically a high level depiction of an example integrated circuit (IC) with different hierarchy levels comprising separate partitions of the example IC;

FIG. 3 illustrates schematically a high level depiction of the example IC of FIG. 2 additionally showing input/output paths of the scan chains;

FIG. 4 illustrates an implementation according to an embodiment of the present invention on the basis of the example architecture described in detail with respect to both FIG. 2 and 3;

FIG. 5a illustrates a flow chart of a power down sequence according to an embodiment of the present invention; and

FIG. 5b illustrates a flow chart of a power up sequence according to an embodiment of the present invention.

### BEST MODE FOR CARRYING OUT THE INVENTION

References will be made in detail to the embodiments of invention examples that are illustrated in the accompanying drawings.

The rapid development of digital electronics, especially complex integrated circuits on the basis of sub-micron and deep-sub-micron process technology, respectively, in their complexity has pushed in parallel the necessity for suitable applicable production testing methodologies to guarantee faultless and defectless electronics.

Modern complex integrated circuit designs such as application specific integrated circuits (ASICs), very large-scale integration (VLSI) circuits, (very) deep sub-micron ((V)DSM) integrated circuits etc implement perquisite hardware structures for production testing. The act of adding logic or features to enhance the testability of a circuit design is generally referred to as design for test and design for testability (DFT), respectively. The design for testability is oriented to the need to enable test development automation and provides access, i.e. observation and control, on internal elements, values and states of the circuits, which are otherwise hidden. One of the most popular and industry-wide testing technology used is based on structural design for test (DFT) technique referred to as scan design and scan-based design, respectively. The scan design for test (DFT) methodology enables the problem of testability to be eased by making circuits appear to be structured as a combinational network or circuit. The scan design for test (DFT) methodology allows control to be obtained over register (logic storage) elements in the circuit under test and register (logic storage) elements to be observed in the circuit under test (CUT). The resulting combinational structure of the circuit under test (CUT) may facilitate the use of automatic test pattern generation (ATPG) for standard logic production testing purposes.

The scan design for test (DFT) methodology is based on the concept of converting all or part of internal state-variable memory elements into sequential scannable elements of a circuit under test (CUT) by overlying a sequential in/out shift register structure to enable controllability and observability of the internal state-variable memory elements. The sequential in/out shift register structure is referred to as scan path or scan chain. The internal state-variable memory elements relate to internal latches, internal registers and the like and conventionally the scannable elements are also designated as scannable cells and scan cells, respectively.

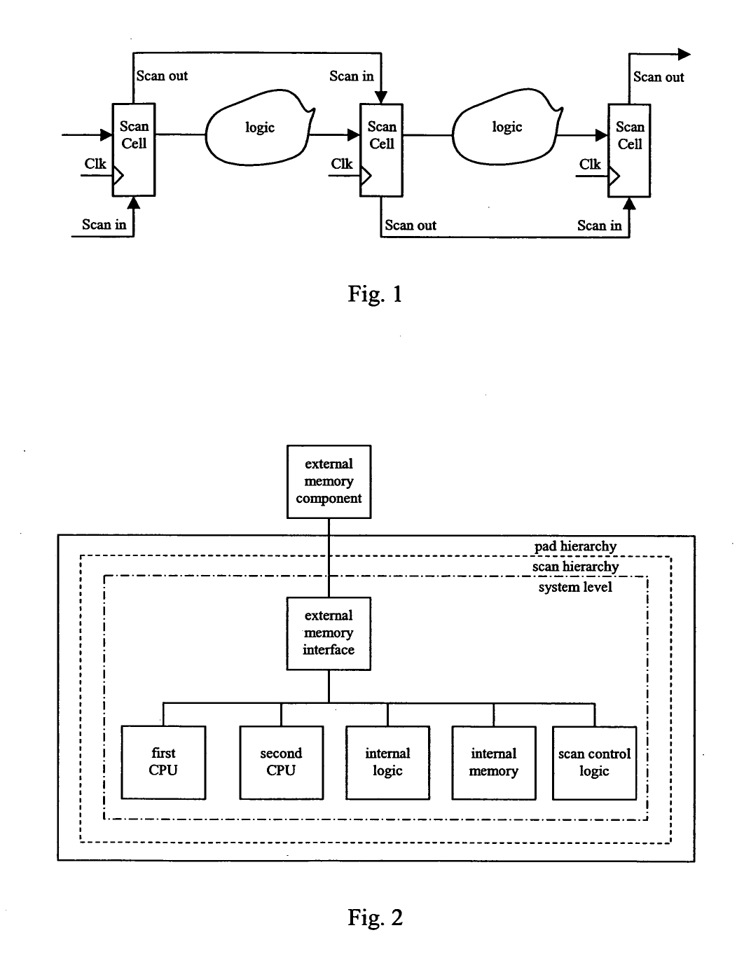

The present invention is implemented on such currently available scan test methodology and technique, respectively, where internal state-variable memory elements are inter-connected in the form of one or more sequential scan chains. That means that in scan mode, i.e. during the scan testing process, the state-variable memory contents of the circuit under test (CUT) can be read out in a sequential format using the scan chains which appear as shift registers driven by a clock signal. A principle depiction of such a sequential chain topology is illustrated in FIG. 1. FIG. 1 illustrates schematically a scan chain within an example circuit under test. In principle, each scan chain constituted by sequentially inter-connected scan cells uses a couple of terminals comprising a scan input to provide to force values into the state-variable memory elements of the circuit and a scan output to observe values of the state-variable memory elements of the circuit. A scan-enable signal (not shown in FIG. 1) places the reconfigured scan cells on the applicable scan chain with data shifted via the scan input whereas data exits the circuit under test via the scan output. A clock signal (CLK) drives the sequential shifting of the scan chain described above. The scan-enable signal and the clock signal are dedicated while scan input and scan output may be shared.

Scan cells are available in various types depending on whether only testing operations will be executed (denoted as capture cell) or simulation operations as well. The types of scan cells include for instance universal cells with two multiplexers and master and shadow latch to support capturing (i.e. scanning out of data, testing) and updating (scanning in of data, simulating), capture cells with one multiplexer and master latch to support capturing only, update cells with one multiplexer, master and shadow latch to support updating and further specific cells. The above enumeration of scan cell types is given as a way of illustration and the present invention is not limited to any specific implementation of scan chains comprising scannable elements.

The implementation of scan cells and scan chains within integrated circuits such as application specific integrated circuits (ASICs) and in particular in modem very large-scale integration (VLSI) circuits causes an extra overhead in each state-variable memory element (internal registers, internal latches etc) to allow for scan testing. The overhead is accepted due to the resulting testability of the circuits performed during manufacturing to ensure faultless operation of the circuits. Moreover, in complex integrated circuits such as application specific integrated circuits (ASICs) and very large-scale integration (VLSI) circuits having a huge number of state-variable memory elements and consequently requiring also a huge number of scan cells the scan cells are typically organized in several separate scan chains being arranged in parallel. The organization and structuring of scan cells in sequential scan chains varies in circuits due to their complexity and testing requirements. Conventionally, the parallelism of scan chains meets the requirement of circuit testing within a suitable period of time.

It shall be noted that the implementation and realization of scan chains is not part of the present invention, although the present invention utilizes scan chains being implemented in a circuit. A main issue of the present invention is based on the inventive concept that scan chains are adequately employable to allow for capturing data from the internal state-variable memory elements of a circuit and restoring (in the sense of the aforementioned updating function) the internal state-variable memory elements on the basis of data such as previously captured data. Consequently, a currently present operational state of a circuit under test is capturable in order to enable a retaining of this operational state, which results in the possibility of restoring this operational state at any moment in time if requested.

As stated above, the number of parallel scan chains varies in circuit products but in larger circuits, e.g. ASICs and especially VLSI circuits, the number of chains easily exceeds the number of hundreds or even thousands. The presence of numerous scan chains provides the flexibility to select which internal state-variable memory elements of the circuit will be captured with the capability to be restored afterwards. However, it may be more adequate to partition a given architecture of a circuit into scan hierarchies such that scan chains of each partition and each hierarchy can be employed according to the present invention, respectively.

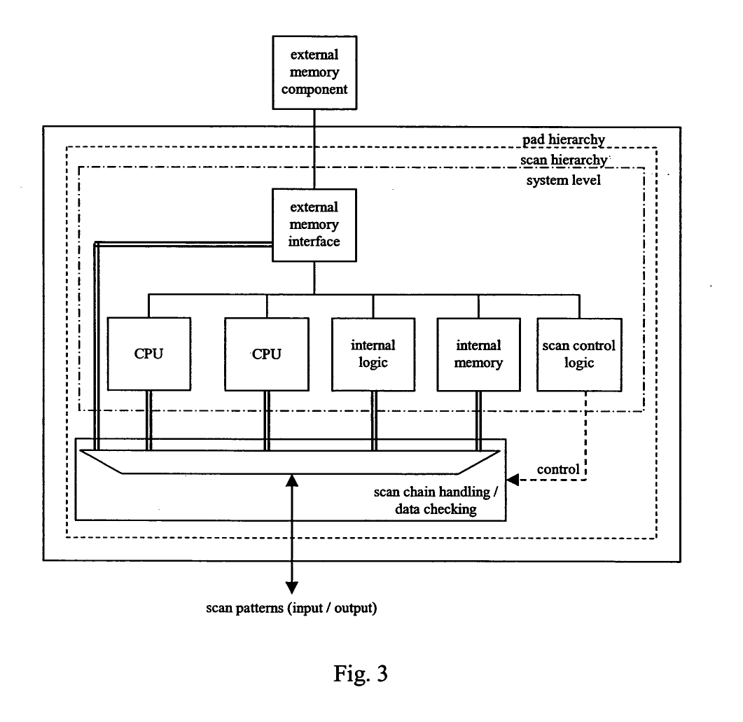

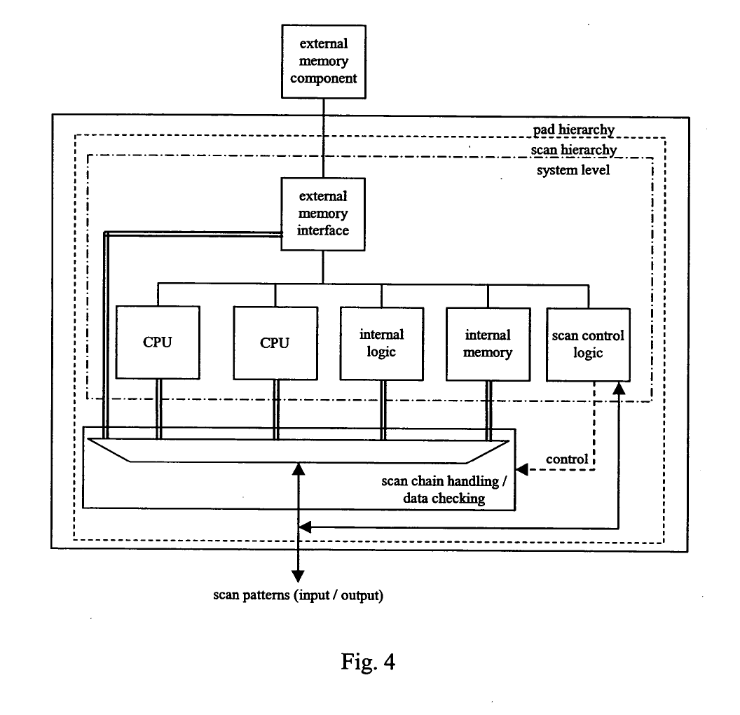

FIG. 2 illustrates schematically a high level depiction of an example integrated circuit (IC) with different hierarchy levels. The pad hierarchy level comprises the complete example integrated circuit and relates primarily to the outside appearance of the integrated circuit, i.e. the inputs and outputs of the integrated circuit. The system hierarchy level comprises the functional portion of the example integrated circuit, which relates to the functional operation thereof. The scan hierarchy level is interposed between pad hierarchy and system hierarchy level and comprises specific hardware precautions required to enable scan testing. The sectioning of the hierarchy levels as mentioned above will become more clearly with reference to the description referring to FIG. 3.

The system hierarchy level comprising the functional portion of the example integrated circuit may further be structured into several separate partitions of the integrated circuit. Each separate partition may relate a specific functional module being arranged within the integrated circuit and serving substantially for a specific functionality. The example integrated, which may represent a system logic module, is for instance partitioned into several separate modules including in a way of illustration a first central processing unit (CPU) a second central processing unit (CPU), an internal logic, an internal memory and an external memory interface (IF) which are interconnected via a common bus structure.

A further partitioning of the example integrated circuit may allow for establishing one or more separate power domains (not shown) within the integrated circuit. Power domains serve to selectively control power supply of the partitions of the integrated circuit comprised thereby. A power controller or power control logic (not shown) may serve to control the power supply to each power domain, i.e. the power control logic can be used to switch between power modes comprising for instance normal power mode (and active mode, respectively) and low power mode.

In principle the aforementioned partitioning of integrated circuits into functional modules and power domains is done independently from each other, i.e. the power domains comprise partitions of the complex circuit architecture different from partitions comprised by the modules. Nevertheless, it may be useful to at least partially match power domains and functional modules. For instance each functional module may be a power domain or a power domain may comprise several functional modules. Moreover, due to the partitioning the separate functional modules and the separate power domains provide each for one or more separate independent scan chains, respectively, which allow for selective access to the functional modules and power domains for capturing and/or restoring as required. That means that specific access to one functional module or one power domain for specifically saving and/or restoring its internal state-variable memory contents is possible.

In the following description it shall be assumed that each of the modules depicted in FIG. 2 represents likewise an independent power domain, wherein each module/power domain provides for independent scan chains.

FIG. 3 illustrates schematically a high level depiction of the example integrated circuit of FIG. 2 additionally showing input/output paths of the scan chains of the separate functional modules. The input/output paths of the scan chains shown in FIG. 3 in the form of double-styled lines are routed to a scan chain handling module which is controlled by a scan control logic. Conventionally, the number of parallel scan chains in complex circuit architecture is so high that only a selected part of the scan chain input/output is lead though to the outside via a number of input/output terminals or pins. The selected input/output may be obtained by the scan chain handling module under control of a scan control logic serving for instance as a selective demultiplexer/multiplexer and/or implementing compression/decompression technology.

In principle, a demultiplexer serves to divide a single sequential data stream into several (sequential) parallel data streams, whereas the multiplexer serves to put together several (sequential) parallel data streams into a single sequential data stream. Correspondingly, a demultiplexer is connected between one or more external scan input terminals/pins of the integrated circuit and internal separate parallel scan chains to reduce the number of external scan input terminals/pins. Likewise, the multiplexer is connected between internal separate parallel scan chains and external scan output terminals/pins of the integrated circuit to reduce to number of external scan output terminals/pins.

The compression/decompression technology relates to the problem that with increasing complexity of integrated circuits the number of scan cells rises in parallel resulting in testing times, test pattern generation and/or test pattern volumes which are not economical any more. Compressing technology has been developed to speed up testing time and/or to reduce test pattern volume. Embedded deterministic test (EDT) methodology is one example technology, which is used to overcome the aforementioned problems of standard ATPG technology in testing times and test pattern volumes. A so-called decompressor is located between external scan inputs and the internal scan chains. Further, a so-called selective compactor is inserted in the internal scan chains and the external scan outputs. A detailed description of the embedded deterministic test (EDT) methodology shall be omitted, but the implementation embedded deterministic test (EDT) methodology presents a number of scan chains to an outside (circuit-external) tester, which is significantly smaller that the actually implemented number of scan chains (up to a factor of 10). Since the scan chains provided to external and the internal scan chains are balanced, the internal scan chains are shorter by the reduction factor of the number, wherein the length relates to the number of scan cells sequentially interconnected in an internal scan chain. The skilled reader will appreciate that shorter scan chains are useful in view of the present invention.

The implementation of scan chains, which allow for shifting in/out scan patterns (test patterns and test result patterns), and demultiplexers/multiplexers and compression/decompression technology is known in the art and is out of the scope of the present invention.

Whereas the aforementioned functional modules including the scan control logic can be associated with the system level, the scan chain handling module may be assigned to the scan hierarchy level which serve to put together the separate parallel scan chains of the modules and power domains, respectively. In result the scan hierarchy level will be superordinated to the system level.

The aforementioned designs and structures thereof will be reused in the present invention, an embodiment of which will be discussed in detail in the following.

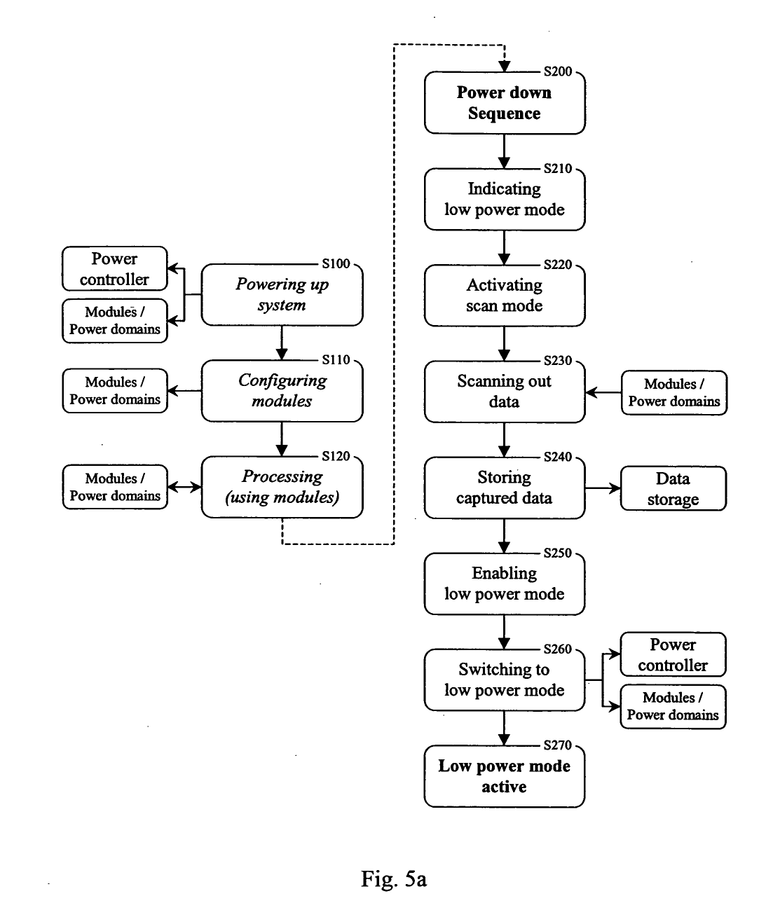

FIG. 4 illustrates an implementation according to an embodiment of the present invention on the basis of the example design described in detail with respect to both FIG. 2 and 3. The implementation is based on improved/enhanced functionality of the scan control logic providing for new control functions in the scan control logic and the scan chain handling module providing additional demultiplexer/multiplexer functionality. The enhanced scan control logic according to an embodiment of the invention serves for capturing data from the functional modules/power domains, for maintaining/retaining captured data and for restoring captured data. Therefor, the scan control logic controls the scan chain handling module which additionally provides for a data communication path to the scan control logic via the additional demultiplexer/multiplexer functionality such that input to the scan chains as well as output of the scan chains can be fed by the enhanced scan control logic and redirected to the enhanced scan control logic, respectively.

The capturing/scanning out capability provided by the scan chains is employed to capture an operational state of one or more modules or power domains by capturing the data contents of internal state-variable memory elements (internal registers) via one or more corresponding scan chains, on the basis which the operational state is resumed when the captured data is restored via the scan chains to the internal state-variable memory elements (internal registers). The updating/scanning in capability provided by the scan chains is employed to restore an operational state of one or more modules or power domains by updating internal state-variable memory elements via one or more corresponding scan chains with the captured data. The restoring of an operational state of a module could be understood as a return of the module into an operational state, in which the module has been at the moment of the capture of the operational state.

The captured data are stored in an adequate storage component such that a later restoring is performable. The storage component may be any storage component, in particular a non-volatile storage such as non-volatile memory of conventional or future type. Depending on the design and the amount of captured data the storage component may be realized as an internal memory or otherwise as an external memory. Conventionally, internal memory is faster, less power consuming and the implementation is easier. Typically, external memory is cheaper, especially in case the amount of captured data is large.

It shall be noted that there are numerous possibilities of the implementation of power down sequences and power up sequence, respectively, embodiments of which will be discussed in the following description. A suitable implementation may be based on software comprising code sections on the basis of which a processor is able to control the saving and restoring function of the operational state. Moreover, such an implementation can also provide the possibility to keep constant configuration values for one or more internal registers and thus there is no need to capture the internal registers before going to power down mode. Alternatively, the same functionality can be obtained by (automatic) hardware-based implementations.

In any case it will be configurable whether or which internal register are captured in conjunction with a power down sequence. Likewise it will be configurable in any case whether or which internal registers are restored in conjunction with a power up sequence. These parameters can be configured individually for each scan chain.

Partial implementations where some possibilities are limited are also possible.

The following embodiments of a power down sequence and a power up sequence are embodied as completely automatic scan based capture and restore mechanisms.

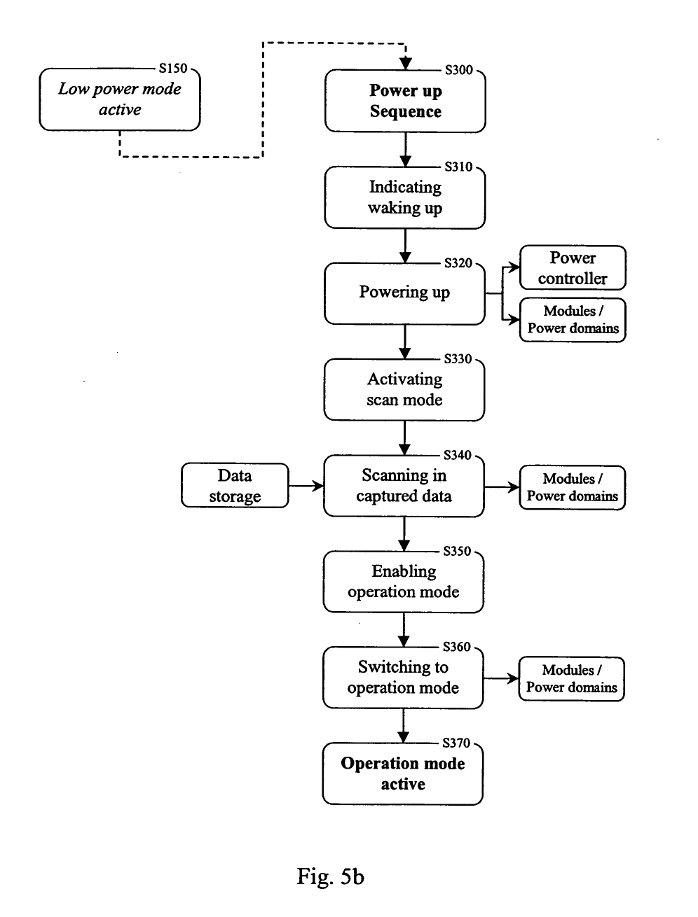

FIG. 5a illustrates a flow chart of a power down sequence according to an embodiment of the present invention.

In an operation S100, a system is powered up. The system comprises a complex circuit architecture including one or more separate modules being partitions of the circuit architecture. The complex circuit architecture is provided with test scan capability on the basis of one or more scan chains, where test patterns and test pattern results can be shifted in/out of the scan chains as required for automatic test pattern generation (ATPG) methodology. The scan chains should be implemented as parallel scan chains. The one or more modules are associated with one or more power domains each of which allow for powering associated module(s) in at least an active/operation mode corresponding to a normal power mode and a low power mode in which the power consumption of the module(s) is reduced relative to the operation mode. The powering of the modules/power domains is for instance controlled by a dedicated power control logic (power controller) adapted to switch between the different available power modes selectively for each power domain. The powering up of the system comprises accordingly a powering up of the modules and the power domains, respectively, which are under control of the power control logic.

In an operation S110, the modules are configured corresponding to their functionality and their tasks to be performed. The configuring may be understood as an initialization of the modules or as an initiating of the modules with data required for performing a task.

In an operation S120, the configured modules take part in the processing performed by the system, which uses the modules adequately in accordance with their capabilities and functionality.

The operations S100 to S120 apply in their general way to all systems with complex integrated circuit design and in particular to processor-based integrated circuit design as such known in processor based consumer electronics. Nevertheless, the present invention relates commonly to any kind of combinational and/or sequential circuits/logic having internal registers, latches and the like.

In an operation S200, at least one module associated with at least one power domain is to be switched into a low power mode, respectively and the powering down sequence is started.

In an operation S210, the switching into the low power mode is signalized by a low power mode indication. The indication may be caused by a task operated on the system. In principle the indication may be a hardware-generated or software-generated indication. In case of a processor-based system the indication may be generated by software executed on the system and carried out by the processor.

In an operation S220, the indication causes the addressed modules to activate the scan (testing) mode which implies the provision of scan chain functionality as described above in detail. The activation of the scan mode may be obtained by supplying the addressed modules or the power control logic with an adequate signal.

In an operation S230, the contents of the internal registers is captured as data during the scan mode from the modules in scan mode. The capturing allows capture of the complete data contents provided in the modules and accessible via the scan chains by the scanning out process, but the capturing may alternatively relate to a selective capturing of contents being a part of the accessible total contents of the internal registers such that the captured data is limited to that data contents which is actually required for restoration afterwards.

In an operation S240, the captured data is stored for instance in a circuit-internal or circuit-external storage such as a memory or a logic. The memory may be implemented as non-volatile or volatile memory depending on whether the memory should retain the captured data powered or unpowered. In principle, any type of data storage can be employed; the invention is not limited to a specific implementation of the data storage.

In an operation S250, the capturing of the data is completed and the modules and the power control logic indicate that the switching into the low power mode is enabled.

In an operation S260, the addressed modules are switched into the low power mode and in an operation S270 the low power mode of the addressed modules is active. The low power mode of the addressed modules will be maintained as long as needed.

It should be noted that the capturing/saving/rescuing of internal register states within the addressed modules is necessary in case the low power mode into which the modules are to be switched is accompanied by loss of the internal register states. The above-stated operations relating to the power down sequence according to an embodiment of the invention can be performed by the scan control logic which may be realized in hardware and eventually at least partly in software. Hardware modifications to available integrated circuit designs needs to be carried out to enable scanning out of the contents of the internal registers into a data storage and/or scanning in of data contents provided by a data storage into the internal registers.

FIG. 5b illustrates a flow chart of a power up sequence according to an embodiment of the present invention.

In an operation S150, at least one mode associated with at least one power domain is in low power mode and is requested to return into operation mode (active mode, normal power mode) which may also designated as power mode.

In an operation S300, the powering up sequence is started in order to switch finally the addressed modules into operation mode.

In an operation S310, the switching into the operation mode is signalized by a waking up indication. The indication may be caused by a task operated on the system. In principle the indication may be a hardware-generated or software-generated indication. In case of a processor-based system the indication may be generated by software executed on the system and carried out on the processor.

In an operation S320, the addressed modules are re-powered, i.e. the previously active low power mode is exited and the power supply of the addressed modules is switched to normal operation power. The powering of the addressed modules may be under control of the power control logic responsible for switching the power supply.

In an operation S330, the addressed and re-powered modules switch into the scan (testing) mode, which implies the provision of scan chain functionality as described above in detail. The activation of the scan mode may be obtained automatically after re-powering or may be obtained by supplying the addressed modules or the power control logic with an adequate signal.

In an operation S340, the retained data captured and stored before is read out from the data storage and is employed for updating the internal registers of the addressed modules via the scan chains by a scanning-in process. In accordance with the capturing of the data performed before, at least a part of the internal registers are updated by the captured data.

In an operation S350, the restoring of the addressed modules on the basis of the captured and retained data is completed and a signal is provided which indicates the completion to signalize the enabling of the operation mode (normal power mode, active mode).

In an operation S360, the addressed modules are switched into operation mode and in an operation S370, the operation mode of the addressed modules is active. The operation mode of the addressed modules will be maintained as long as needed.

The inventive concept, on which the present invention is based, allows principally for saving and restoring the state of all flip-flops within an integrated circuit resulting also in a saving and restoring of internal state machines. The impact on the hardware design is minimal in case external memory is employed for retaining and even in case of internal memory the impact on the hardware design remains minimal (causing an increase of about 0.5% to 1% in size)

The front end design and especially the front end register transfer level (RTL) design requires no modifications which is an important feature. The inventive technique can be implemented in a fine granularity, i.e. an integrated circuit such as an application specific integrated circuit (ASIC) is partitioned into several power domains and the inventive technique can be applied on each of the power domains. The partitioning into power domains is geared to the need for optimization of active mode power consumption. The leakage power can be totally controlled of during low power mode for each power domain in question. The remaining leakage power is caused by the memory in which the states (captured data) are saved. However, memory retention techniques can be used for the internal memory to minimize the total leakage. For instance, the employment of 500 to 1000 deep chains and custom wide memory at system clock speed of approximately 40 MHz results in a transition time in a range from about 10 μS to 25 μS.

The inventive concepts of the present invention requires hardware modifications on an integrated circuit in question concerning the specific memory which is also needed to be instantiated and the scan chains routed for it. Furthermore, scan control logic needs to be implemented for entering into and exiting from the low power mode. However, the required hardware implementations and modifications are straightforward and have only a slight impact on current designs concerning the implementation of a routing of data from the internal scan chain input/outputs to a specific memory and the needed control logic for signaling exists anyway in integrated circuits fulfilling the design for test (DFT) requirements.

Referring back to FIG. 4, the embodiment of an integrated circuit schematically illustrated therein relates to single integrated circuit such as known from application specific integrated circuits (ASICs), having several independent operational modules and/or power domains. Those skilled in the art will appreciate on the basis of the embodiments provided and described in this invention that the inventive concept is not limited to such a specific implementation. The inventive concept is also applicable on a system comprising one or more integrated circuits each implementing scan chains for production testing. One or more scan control logics such as that one described above are further included in the system either separate from the integrated circuits or implemented in the integrated circuits. The one or more scan control logics serve accordingly for updating and/or observing of the state-variable memory elements of the integrated circuits to allow restoring and/or saving of contents of the state-variable memory elements which results in restoring and/or saving of operational states of the integrated circuits.

Nevertheless the integrated circuits of such a system may present a structured design comparable with that illustrated in accordance with the embodiment referred to in FIG. 4. That means that one or more of the integrated circuits of the system may comprise modules/power domains, which are operable with different power modes (power mode, low power mode . . . ) as enlightened above.

Moreover, the system comprises also one or more data storages for providing data for the update function and for providing data storage capacity to store captured data.

Without limiting the present invention, an example embodiment of such a system comprises at least one but also several separate integrated circuits, a central scan control logic, a power control logic and a data storage. The central scan control logic serves for all integrated circuits; i.e. the scan control logic allows each integrated circuit to be switched into scan mode to allow access to state-variable memory elements within the integrated circuit and handle data communication between scan chains and data storage. The power control logic controls the powering of the integrated circuits; i.e. switches selectively the integrated circuits (or partitions thereof) between power mode and low power mode.

1. Method for controlling leakage power in an integrated circuit having several scan chains allowing for updating internal state-variable memory elements with test patterns and operable with at least a power mode and a low power mode,
wherein an operational state of at least one partition of said integrated circuit operated with said low power mode is restored by
retrieving data from a data storage; and
scanning in said data via at least a part of said scan chains to update at least a part of said internal state-variable memory elements.

2. Method according to claim 1, wherein said scanning in is enabled by
switching said partition into said power mode; and
switching said partition into a scan mode.

3. Method according to claim 1, wherein said data is default data to restore said integrated circuit into a default operational state.

4. Method according to claim 1, wherein said several scan chains allow for observing said internal state-variable memory elements,
wherein said operational state of said partition of said integrated circuit operated with said power mode is saved by
capturing data by observing at least a part of said internal state-variable memory elements via at least a part of said scan chains; and
storing said captured data in said data storage.

5. Method according to claim 4, wherein said observing is enabled by
switching said partition into scan mode,
wherein said partition is finally switched into said low power mode.

6. Method according to claim 1, wherein said integrated circuit comprises at least one power domain comprising at least a part of said integrated circuit and operable with at least said power mode and said low power mode; wherein said scan chains are associated with said at least one power domain.

7. Method according to claim 1, wherein said low power mode causes loss of contents of said internal state-variable memory elements.

8. Method according to claim 1, carried out by a scan control function.

9. Method according to claim 8, wherein said scan control function is hardware-implemented.

10. Method according to claim 9, wherein said scan control function is at least partly software-implemented.

11. Integrated circuit having an implemented leakage power control, having several scan chains allowing for updating internal state-variable memory elements with test patterns and being operable with at least a power mode and a low power mode,
wherein said scan chains are operable for restoring an operational state of at least a partition of said integrated circuit by employing at least a part of said scan chains of said partition for updating at least a part of said internal state-variable memory elements with data retrieved from a data storage.

12. Integrated circuit according to claim 11, wherein one or more inputs of said scan chains are coupled via a data path to said data storage.

13. Integrated circuit according to claim 11, wherein said data is default data to restore said partition of said integrated circuit into a default operational state.

14. Integrated circuit according to claim 11, wherein said several scan chains allow for observing said internal state-variable memory elements,
wherein said scan chains are operable for saving an operational state of said partition by employing at least a part of said scan chains of said partition for observing at least a part of said internal state-variable memory elements to capture data therefrom to be stored in said data storage.

15. Integrated circuit according to claim 14, wherein one or more outputs of said scan chains are coupled via said data path to said data storage.

16. Integrated circuit according to claim 14, further comprising a scan control function enabling said updating, enabling said saving, or both.

17. Integrated circuit according to claim 11, wherein said scan chains are carried out in accordance with scan design for testability of said integrated circuit to allow for production testing.

18. System for controlling leakage power comprising at least one integrated circuit and a data storage; wherein said integrated circuit has several scan chains allowing for updating internal state-variable memory elements with test patterns and is operable with at least a power mode and a low power mode,
wherein said scan chains are operable for restoring an operational state of at least a partition of said integrated circuit by employing at least a part of said scan chains of said partition for updating at least a part of said internal state-variable memory elements with data retrieved from said data storage.

19. System according to claim 18, wherein one or more inputs of said scan chains are coupled via a data path to said data storage.

20. System according to claim 18, wherein said data is default data to restore said partition of said integrated circuit into a default operational state.

21. System according to claim 18, wherein said several scan chains allow for observing said internal state-variable memory elements,
wherein said scan chains are operable for saving an operational state of said partition by employing at least a part of said scan chains of said partition for observing at least a part of said internal state-variable memory elements to capture data therefrom to be stored in said data storage.

22. System according to claim 21, wherein one or more outputs of said scan chains are coupled via said data path to said data storage.

23. System according to claim 21, further comprising a scan control function enabling said updating, enabling said saving, or both.
